(19) United States
(12) Patent Application Publication
(10) Pub. No.: US 2007/0091566 A1
(43) Pub. Date: Apr. 26, 2007

(54) FAN DUCT AND HEAT DISSIPATION MODULE COMPRISING THE SAME

(75) Inventor: Ke Sun, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., TU CHENG (TW)

(21) Appl. No.: 11/308,744

(22) Filed: Apr. 28, 2006

(30) Foreign Application Priority Data
Oct. 24, 2005 (CN) 200510100601.0

(51) Int. Cl. H05K 7/20

(52) U.S. Cl. 361/695

(57) ABSTRACT

A heat dissipation module includes a heat sink (40) mountable above a heat-generating component, a fan duct (10), and a fan (50). The fan duct accommodating the heat sink includes a top wall (11), and a pair of sidewalls (13) extending down from opposite sides of the top wall. An air inlet and an air outlet (18) are formed at opposite ends of the fan duct. A sidewall of the pair of sidewalls defines an opening (19) therein. A guiding tab (21) extends inward from a side of the opening adjacent the air outlet. The fan is mounted to the air inlet of the fan duct.

### FIELD OF THE INVENTION

The present invention relates to fan ducts, and particularly to a fan duct for auxiliary cooling of a CPU and electronic components around the CPU on a circuit board.

### DESCRIPTION OF RELATED ART

Electronic devices, such as Central Processing Units (CPUs), frequently generate large amounts of heat during normal operation, which can destabilize operation and cause damage. Oftentimes, a heat dissipating assembly is used to dissipate heat from the electronic devices. The heat dissipating assembly frequently includes a fan facilitating removal of heat from the electronic devices.

Conventionally, a heat sink is mounted on a CPU inside a computer. A fan is directly mounted on the heat sink. The fan generates currents of air flowing through and around the heat sink, causing heat to be dissipated into the surrounding air.

Fan ducts have been developed to allow outside cooling air to flow through heat dissipating assemblies to dissipate heat from CPUs. A conventional fan duct assembly is disclosed in U.S. Pat. No. 6,717,814. The fan duct assembly includes a fan duct receiving a heat sink mounted above a CPU, and a fan secured to an air inlet of the fan duct. The fan duct facilitates greater efficiency of heat dissipation from the CPU. However, the fan duct may not be able to be helpful in cooling electronic components mounted around the CPU.

What is desired, therefore, is a fan duct which facilitates cooling of a CPU as well as electronic components around the CPU on a circuit board.

### SUMMARY OF THE INVENTION

An exemplary heat dissipation module includes a heat sink mounted above a heat-generating component, a fan duct, and a fan. The fan duct accommodating the heat sink includes a top wall, and a pair of sidewalls extending down from opposite sides of the top wall. An air inlet and an air outlet are formed at opposite ends of the fan duct. A sidewall of the pair of sidewalls defines an opening therein. A guiding tab extends inward from a side of the opening adjacent the air outlet. The fan is mounted to the air inlet of the fan duct.

Other advantages and novel features will become more apparent from the following detailed description when taken in conjunction with the accompanying drawings, in which:

### BRIEF DESCRIPTION OF THE DRAWINGS

FIG. 1 is an exploded isometric view of a heat dissipation module in accordance with a first preferred embodiment of the present invention, together with a circuit board, the heat dissipation module includes a fan duct;

FIG. 2 is an isometric view of the fan duct of FIG. 1, but viewed from another aspect;

FIG. 3 is an assembled view of FIG. 1;

FIG. 4 shows the heat flow simulation analysis according to the heat dissipation module of FIG. 3;

FIG. 5 is an isometric view of a fan duct in accordance with a second preferred embodiment of the present invention;

FIG. 6 is an isometric view of a fan duct in accordance with a third preferred embodiment of the present invention; and

FIG. 7 is an isometric view of a fan duct in accordance with a fourth preferred embodiment of the present invention.

### DETAILED DESCRIPTION OF THE INVENTION

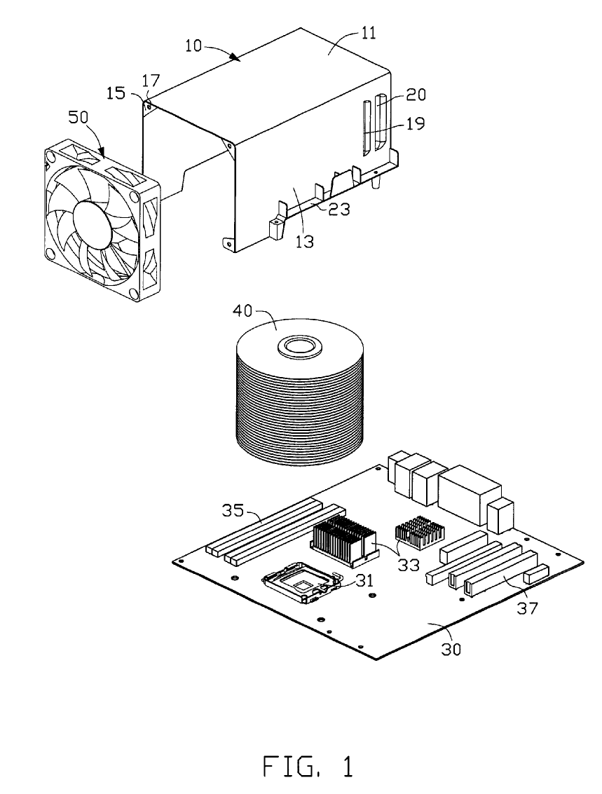

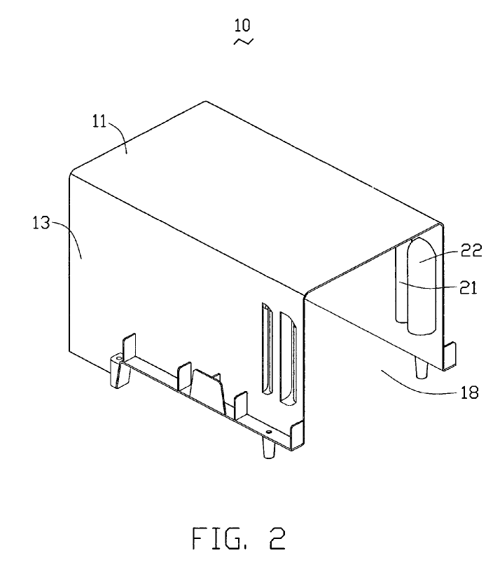

Referring to FIGS. 1 and 2, a heat dissipation module in accordance with a preferred embodiment of the present invention is shown for a CPU (not shown) and electronic components around the CPU mounted to a circuit board 30. The CPU is mounted to a socket 31 of the circuit board 30. Some electronic components (not shown) are mounted under heat sinks 33 and at an end of the CPU. Some electronic components 35, 37 are mounted at opposite sides of the CPU. The heat dissipation module includes a heat sink 40 mounted above the CPU, a fan duct 10, and a fan 50.

The fan duct 10 includes a top wall 11, and a pair of sidewalls 13 extending down from opposite sides of the top wall 11. An air outlet 18 is formed at an end of the fan duct 10. A tab 15 is formed at each of four corners of an opposite end of the fan duct 10. A mounting hole 17 is defined in each tab 15. A first opening 19 and a second opening 20 parallel to the first opening 19 are defined in each sidewall 13. A width of the second opening 20 is greater than that of the first opening 19. An arc-shaped first guiding tab 21 extends in from a side of the first opening 19 adjacent the air outlet 18. An arc-shaped second guiding tab 22 extends in from a side of the second opening 20 adjacent the air outlet 18. A length of the second guiding tab 22 is greater than that of the first guiding tab 21. A securing portion 23 is formed at a bottom portion of each sidewall 13 for mounting the fan duct 10 to the circuit board 30.

The fan 50 defines a through hole (not labeled) at each of four corners thereof, corresponding to the mounting holes 17 of the fan duct 10.

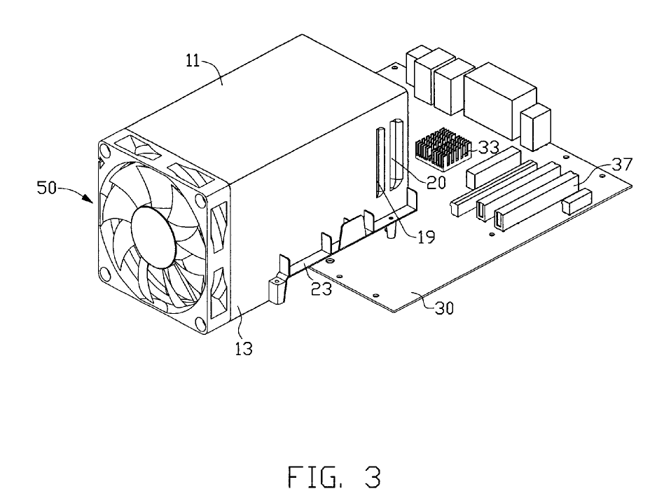

Referring also to FIG. 3, in assembling the fan 50 to the fan duct 10, the fan 50 is attached to the fan duct 10, with the through holes thereof aligning with the corresponding mounting holes 17 of the fan duct 10. Four fasteners (not shown) are consecutively inserted through the corresponding through holes of the fan 50 to be engaged in the corresponding mounting holes 17 of the fan duct 10. Thus, the fan 50 is secured to an air inlet of the fan duct 10 opposite to the air outlet 18.

The combined assembly of the fan duct 10 and the fan 50 are secured to the circuit board 30 via the securing portion 23 of the fan duct 10. The fan duct 10 accommodates the heat sink 40 mounted above the CPU.

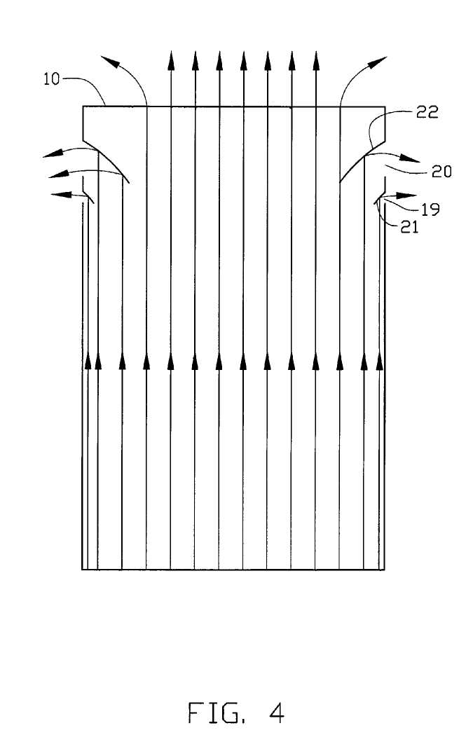

Referring also to FIG. 4, when used, the fan 50 draws air into the fan duct 10. The air flows over the heat sink 40 for a cooling effect, and then flows through the air outlet 18 for dissipating heat from the heat sink 33. A portion of the air flowing through the duct 10 is deflected by the first guiding tabs 21 and the second guiding tabs 22 to flow through the first openings 19 and the second openings 20 to dissipate heat from the electronic components 35, 37. Thus, the fan duct 10 has a cool for the CPU as well as the electronic components around the CPU.

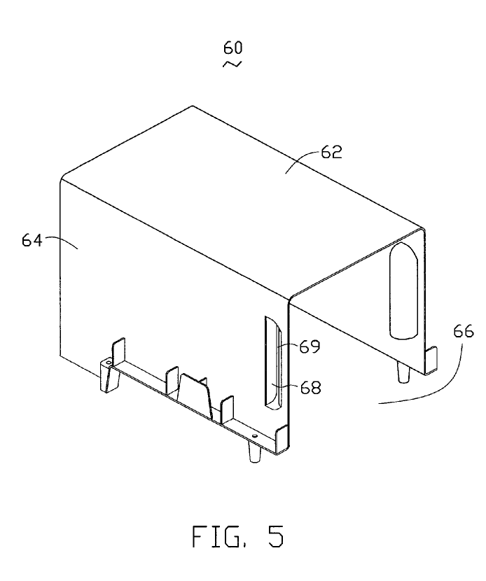

FIG. 5 shows a fan duct 60 in accordance with a second embodiment of the present invention. The fan duct 60 includes a top wall 62, and a pair of sidewalls 64 extending down from opposite sides of the top wall 62. An air outlet 66 is formed at an end of the fan duct 60. An opening 68 is defined in each of the pair of sidewalls 64 adjacent the air outlet 66. An arc-shaped guiding tab 69 extends inward from a side of the opening 68 adjacent the air outlet 66.

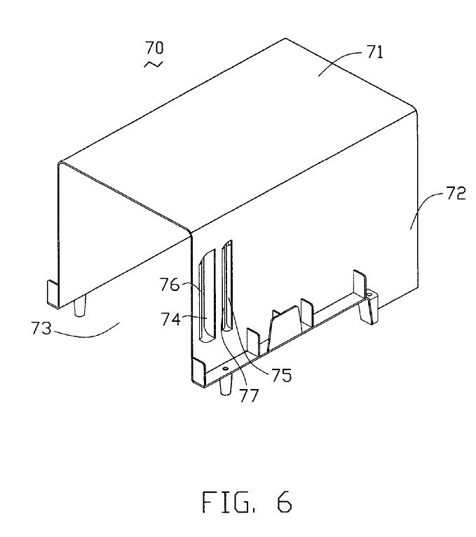

FIG. 6 shows a fan duct 70 in accordance with a third embodiment of the present invention. The fan duct 70 includes a top wall 71, and a pair of sidewalls 72 extending down from opposite sides of the top wall 71. An air outlet 73 is formed at an end of the fan duct 70. A first opening 75 and a second opening 74 are defined in the sidewall 72 of the pair of sidewalls 72 adjacent the air outlet 73. An arc-shaped first guiding tab 77 extends inward from a side of the first opening 75 adjacent the air outlet 73. An arc-shaped second guiding tab 76 extends inward from a side of the second opening 74 adjacent the air outlet 73.

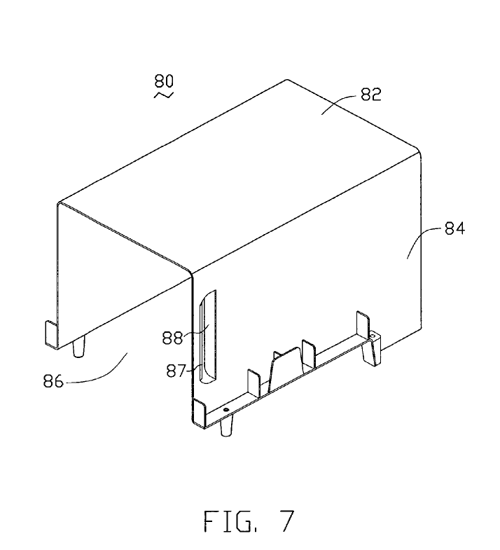

FIG. 7 shows a fan duct 80 in accordance with a fourth embodiment of the present invention. The fan duct 80 includes a top wall 82, and a pair of sidewalls 84 extending down from opposite sides of the top wall 82. An air outlet 86 is formed at an end of the fan duct 80. An opening 88 is defined in the sidewall 84 of the pair of sidewalls 84 adjacent the air outlet 86. An arc-shaped guiding tab 87 extends inward from a side of the first opening 88 adjacent the air outlet 86.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A fan duct comprising:
a top wall; and
a pair of sidewalls extending down from opposite sides of the top wall, at least one sidewall of the pair of sidewalls defining at least one opening, a guiding tab extending inward from a side of the at least one opening.

2. The fan duct as claimed in claim 1, wherein an air outlet is formed at one end of the fan duct, an opposite end of the fan duct is able to receive a fan mounted thereto.

3. The fan duct as claimed in claim 2, wherein the at least one opening comprises a first opening and a second opening parallel to the first opening defined in the at least one sidewall, the second opening is located between the first opening and the air outlet.

4. The fan duct as claimed in claim 3, wherein an arc-shaped first guiding tab extends inward from a side of the first opening adjacent the air outlet, an arc-shaped second guiding tab extends inward from a side of the second opening adjacent the air outlet, a length of the second guiding tab is greater than that of the first guiding tab.

5. The fan duct as claimed in claim 2, wherein the at least one sidewall comprises two sidewalls, and the at least one opening comprises two openings defined in each of the two sidewalls, an arc-shaped guiding tab extends inward from a side of each of the openings adjacent the air outlet.

6. The fan duct as claimed in claim 2, wherein the at least one sidewall comprises two sidewalls, and the at least one opening comprises two first openings defined in each of the two sidewalls respectively, and two second openings defined in each of the sidewalls respectively, each of the second openings is located between the corresponding first opening and the air outlet.

7. The fan duct as claimed in claim 6, wherein an arc-shaped first guiding tab extends inward from a side of each of the first openings adjacent the air outlet, an arc-shaped second guiding tab extends inward from a side of each of the second openings adjacent the air outlet, a length of the second guiding tabs is greater than that of the first guiding tabs.

8. A heat dissipation module comprising:
a heat sink mountable above a heat-generating component;
a fan duct accommodating the heat sink, the fan duct comprising a top wall, and a pair of sidewalls extending down from opposite sides of the top wall, an air inlet and an air outlet formed at opposite ends of the fan duct, at least one sidewall of the pair of sidewalls defining at least one opening, a guiding tab extending inward from a side of the at least one opening adjacent the air outlet; and
a fan mounted to the air inlet of the fan duct.

9. The heat dissipation module as claimed in claim 8, wherein the at least one opening comprises a first opening and a second opening parallel to the first opening defined in the at least one sidewall, the second opening is located between the first opening and the air outlet.

10. The heat dissipation module as claimed in claim 9, wherein an arc-shaped first guiding tab extends inward from a side of the first opening adjacent the air outlet, an arc-shaped second guiding tab extends inward from a side of the second opening adjacent the air outlet, a length of the second guiding tab is greater than that of the first guiding tab.

11. The heat dissipation module as claimed in claim 8, wherein the at least one sidewall comprises two sidewalls, and the at least one opening comprises two openings defined in each of the two sidewalls, an arc-shaped guiding tab extends inward from a side of each of the openings adjacent the air outlet.

12. The heat dissipation module as claimed in claim 8, wherein the at least one sidewall comprises two sidewalls, and the at least one opening comprises two first openings defined in each of the two sidewalls, and two second openings defined in each of the two sidewalls, each of the second opening is located between the corresponding first opening and the air outlet.

13. The heat dissipation module as claimed in claim 12, wherein an arc-shaped first guiding tab extends inward from a side of each of the first openings adjacent the air outlet, an arc-shaped second guiding tab extends inward from a side of each of the second openings adjacent the air outlet, a length of the second guiding tabs is greater than that of the first guiding tabs.
